(19) United States
(12) Patent Application Publication
(10) Pub. No.: US 2023/0295798 A1
(43) Pub. Date: Sep. 21, 2023

(54) METAL OXIDE WITH LOW TEMPERATURE FLUORINATION

(71) Applicant: Lam Research Corporation, Fremont, CA (US)

(72) Inventors: Eric A. PAPE, Santa Cruz, CA (US); Robin KOSHY, Fremont, CA (US)

(21) Appl. No.: 18/017,246

(22) PCT Filed: Jul. 6, 2021
(86) PCT No.: PCT/US2021/040550

§ 371 Date: Jan. 20, 2023

Related U.S. Application Data
(60) Provisional application No. 63/058,852, filed on Jul. 30, 2020.

(51) Int. Cl. C23C 16/40; C23C 16/448; C23C 16/56

(52) U.S. Cl. CPC C23C 16/405; C23C 16/4486; C23C 16/56

(57) ABSTRACT

A method for providing a component for using in a plasma processing chamber is provided, wherein the component has a plasma facing surface. A metal oxide layer is provided on the plasma facing surface of the component. The metal oxide layer is exposed to a fluorine containing gas at a temperature of less than 600° C. for at least 2 hours at a partial pressure of at least 0.1 bar.

### CROSS-REFERENCE TO RELATED APPLICATION

This application claims the benefit of priority of U.S. Application No. 63/058,852, filed Jul. 30, 2020, which is incorporated herein by reference for all purposes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The present disclosure relates to the manufacturing of semiconductor devices. More specifically, the disclosure relates to coating components for plasma processing chambers used in manufacturing semiconductor devices.

During semiconductor wafer processing, plasma processing chambers are used to process semiconductor devices. The plasma processes may deposit on or erode surfaces of the plasma processing chamber. Coatings are used to protect plasma processing chamber components. Ceramic coatings are formed over plasma processing chamber components to provide protection from plasma erosion. Such coatings may be subject to stress due to coefficient of thermal expansion mismatch and fluorination due to exposure to fluorine plasmas, resulting in part failure or the production of contaminants from the part.

### SUMMARY

To achieve the foregoing and in accordance with the purpose of the present disclosure, a method for providing a component for using in a plasma processing chamber is provided, wherein the component has a plasma facing surface. A metal oxide layer is provided on the plasma facing surface of the component. The metal oxide layer is exposed to a fluorine containing gas at a temperature of less than 600° C. for at least 2 hours at a pressure of at least 0.1 bar.

In another manifestation, a component for use in a plasma processing chamber is provided. The component has a component body. A metal oxide containing layer forms a plasma facing surface of the component body, wherein metal oxide containing layer has an increasing fluoridation concentration closer to the plasma facing surface and wherein the metal oxide containing layer has less than 10 parts per million of carbon impurities by mass.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-D are schematic views of a component body processed according to an embodiment.

FIG. 3 is a schematic view of a plasma processing system that may be used in an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

During the processing of semiconductor devices, a plasma processing chamber may be used for plasma deposition, plasma etching, or for other processes used in manufacturing semiconductor devices. Such plasma processing may deposit on and/or etch surfaces of the plasma processing chamber. Components of the plasma processing chambers have surfaces used to maintain the plasma environment. Such components may be aluminum to provide electrical and thermal characteristics that are useful in maintaining the plasma. Aluminum also allows a reduction in weight and cost. A coating on the surface of the aluminum is needed to protect the aluminum surface. To minimize defects, a protective coating may be used to protect the component from erosion. Other components may have component bodies that are ceramic or other brittle material that need protective coatings when used in a plasma processing chamber.

Film stresses at ambient temperature and associated film stresses across a broader temperature range due to CTE (coefficients of thermal expansion) significantly impact the mechanical integrity of thin films or coatings. Lack of mechanical integrity may result in film delamination, spallation, or other defect/particle generating mechanisms. Film stresses are the result of two factors: intrinsic stresses (such as lattice mismatches, defects, etc.) and coefficient of thermal expansion (CTE).

All inhomogeneous material coatings, be the inhomogeneity from morphology (e.g. crystalline structure or rotation) or chemistry (e.g. oxide vs pure metal), have critical thicknesses where intrinsic or CTE based stresses create mechanical problems. These stresses may result in spallation, cracking, decohesion, and delamination in thick anodized aluminum above about 140° C., or atmospheric spray coat (APS) decohesion, delamination, and decohesion when sprayed over aluminum. There are additionally some cracking issues with high temperature deposition or annealed deposition of coatings over ceramic (aerosol deposition (AD) or physical vapor deposition (PVD)). Oxides (e.g. yttria over alumina) or oxyfluorides over oxides are generally less problematic because of lower CTE mismatch than between metals and oxides.

For atmospheric plasma spray (APS) coatings of either yttria or alumina, over aluminum, the substrate temperature must be carefully controlled so that there are adequate, but not too high, compressive stresses on the film due to the CTE mismatch (>20 vs 7 for metal vs oxide). If compressive film stresses are too low, subsequent operation at temperatures above the application temperature will result in film delamination. If compressive film stresses are too high, the coating will buckle as the part cools. This same behavior exists for yttrium oxyfluoride (YOF) based APS coatings, albeit to a lesser degree, since the CTE is about 13. The CTE of a fully fluorinated yttria layer is between about 14 to 21. It is extremely difficult to optimize the surface fluorine content of a film as well as the compressive stresses.

For aerosol deposition (AD) coatings, high temperature fluorination will likely not be viable. Higher temperatures may alter the crystalline microstructure formed through ballistic impact detrimentally. In addition, film stresses from CTE mismatches may create mechanical issues.

This disclosure relates to providing a controlled and low temperature, moderate to high pressure difluoride (F₂) fluorination processes to fluoroconvert oxides to carefully optimized depths while maintaining specific crystalline structures and controlled engineered stresses in multi-layer coatings. For example, coatings may now be oxyfluorides over oxides over metals or oxyfluorides over oxides.

Depths of fluorination may be from tens of nanometers (nm) (in chamber locations where thinner coatings may be acceptable for part lifetimes) to several or tens of microns (thicker coatings may be acceptable for part lifetimes). Depths may also be designed specifically to create stress gradient profiles, or to maintain film stresses within a non-critical region relative to the final operating temperature in the system.

Various embodiments provide fluorinated or oxyfluorinated films that result in low particle counts and low erosion rates. Various embodiments provide fluorinated films where for other deposition processes precursor materials may be extremely difficult to work with, such as aerosol deposition for YOF. Various embodiments provide controlled film stresses to prevent film failure. Embodiments may also provide reduced damage for metal parts that also have anodized layers.

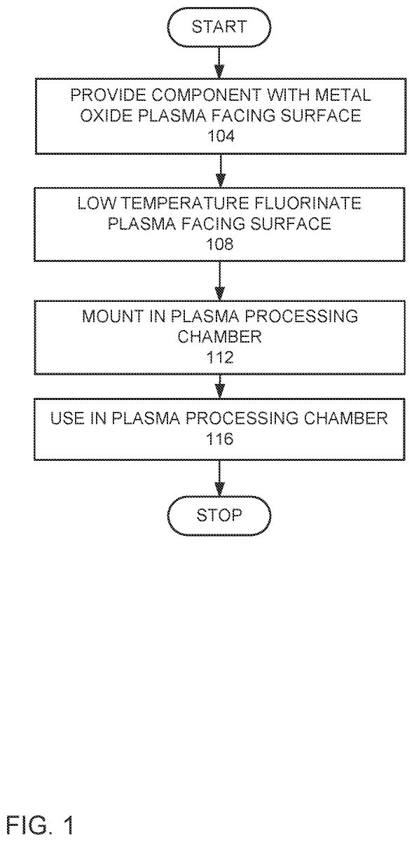

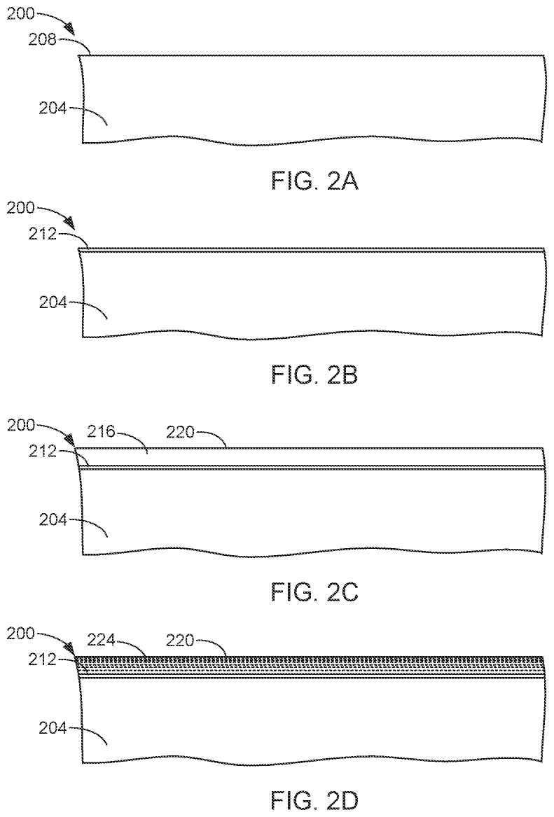

To facilitate understanding, FIG. 1 is a flow chart of an embodiment that provides an oxyfluorinated layer over a plasma facing surface of a component of a plasma processing chamber. In an embodiment, a component with a metal oxide plasma facing surface is provided (step 104). FIG. 2A is a schematic cross-sectional view of part of a component 200 with a component body 204 with a surface 208. In this embodiment, the surface 208 of the component body 204 is anodized forming an anodization layer. FIG. 2B is a schematic cross-section view of the component 200 after an anodization layer 212 has been formed as part of the surface of the component body 204. In addition, in this embodiment, an yttria coating is deposited on the anodization layer 212, using APS. FIG. 2C is a schematic cross-sectional view of the component body 204 after an yttria layer 216 has been deposited by APS. In this embodiment, the yttria layer 216 has a thickness in the range of 10 μm to 500 μm. The outer surface of the yttria layer 216, in this embodiment, is a metal oxide plasma facing surface 220.

The metal oxide plasma facing surface is subjected to a low temperature fluorination (step 108). In this embodiment, the metal oxide plasma facing surface is exposed to a fluorine containing gas of difluorine (F₂) at a pressure of at least 0.1 bar (10 kilopascals (kPa)). The metal oxide plasma facing surface is heated to a temperature of no more than 600° C. for at least 2 hours, while exposed to the fluorine gas. This embodiment is a plasmaless process.

FIG. 2D is a schematic cross-sectional view of the component 200 after the yttria layer has been subjected to the low temperature fluorination (step 108) creating a fluorinated yttria layer 224. The low temperature fluorination transforms part of the metal oxide layer into a fluorinated metal oxide layer. The fluorinated metal oxide layer has a fluorination gradient, where the concentration of fluorine increases closer to the plasma facing surface 220, causing an increasing fluoridation concentration closer to the plasma facing surface 220. The gradient is indicated by the increasing spacing between the dashed lines.

The component is mounted in a plasma processing chamber (step 112). The component is used in the plasma processing chamber (step 116). The yttria layer 216 is exposed to a plasma during plasma processing.

In this example, the fluorinated yttria layer 224 is more resistant to damage caused by fluorination during plasma processing than yttria. The temperature, pressure, and fluorination time are process parameters to control the gradient profile. The gradient profile provides a controlled stress gradient profile. The controlled stress gradient profile prevents stress from being too low. If stress is too low, then during plasma processing at operating temperatures, delamination may occur. If stress is too high, the parts will buckle as the component cools. The gradient profile may be tuned to prevent such problems.

The gradient of the fluorinated yttria layer 224 has an increased concentration of yttrium oxyfluoride (YOF) and a lower concentration of yttria near the surface and a lower concentration of YOF and increased concentration of yttria further away from the surface. The fluorinated yttria layer 224 produces fewer contaminants than an yttrium trifluoride (YF₃) layer. Although fluorinated yttria may be subjected to more fluorination than YF₃, fluorinated yttria may be more resistant to sputtering and other damage caused by ion bombardment than YF₃. The fluorinated yttria may also be more resistant to damage from oxygen containing plasmas that are used in chamber cleaning processes. In addition, forming coatings of YF₃ may be difficult and expensive.

In addition, the APS deposition used in this embodiment is able to deposit the yttria layer 216, while being substantially free of carbon impurities. In this example, carbon impurities are less than 10 parts per million of carbon impurities by mass. As a result, the fluorinated yttria layer 224 has less carbon contaminants than yttrium trifluoride layers. Other embodiments may use other carbon residue free fluorine containing gases such as nitrogen trifluoride (NF₃), carbon tetrafluoride (CF₄), difluorine (F₂), methyl fluoride (CHₓF_{y}, where x and y are greater than or equal to one), sulfur hexafluoride (SF₆), and/or chlorine trifluoride (ClF₃). Such carbon residue free fluorine containing gases leave minimal carbon residue in the fluorinated coating, in order to have the above described purity.

In other embodiments, the plasma facing surface of the component may be of another metal oxide, instead of yttria. For example, the metal oxide may be an oxide of a rare earth element. In another example, the metal oxide is an oxide of a lanthanide. In other embodiments, the metal oxide is an yttrium aluminum oxide, such as one or more of yttrium aluminum garnet (Y₃Al₅O₁₂ (YAG)), yttrium aluminum monoclinic (Y₄Al₂O₉ (YAM)), or yttrium aluminum perovskite (YAlO₃ (YAP)). In other embodiments, the metal oxide is aluminum oxide or magnesium oxide (MgO) or spinel (MgAl₂O₄). In some embodiments, the metal oxide layer is a metal oxide containing layer. In some embodiments, the metal oxide layer is a conglomerate of a skeleton of one metal oxide and a filler of another metal oxide.

In various embodiments, the component body 204 may comprise at least one of an electrically conductive or dielectric material. Examples of materials for component bodies 204 of a dielectric material are alumina, titanium oxide (TiO₂), silicon carbide (SiC), machinable glass-ceramic, such as Macor manufactured by Corning Inc, and yttria. Examples of materials for component bodies 204 of electrically conductive material are aluminum, aluminum alloy, or metal matrix composites, such as AlSiC. The component body 204 may be ceramic, polycrystalline, multicrystalline, or monocrystalline. In some embodiments, where the component body is of a metal oxide material, a layer of another metal oxide material may be deposited and then fluorinated. In other embodiments, where the component body 204 is of a metal oxide material, another metal oxide layer is not deposited, but instead at least one surface of the component body 204 is fluorinated (step 108).

In various embodiments, different processes may be used to form the metal oxide layer on a surface of the component body 204. In various embodiments, thermal spraying and aerosol deposition may be used to deposit a metal oxide layer on a surface of a component body 204.

Aerosol deposition is achieved by passing a carrier gas through a fluidized bed of solid powder mixture. Driven by a pressure difference, the powder mixture particles are accelerated through a nozzle, forming an aerosol jet at its outlet. The aerosol is then directed at the surface of the component body 204, where the aerosol jet impacts the surface with high velocity. The particles break up into solid nanosized fragments, forming a coating. Optimization of carrier gas species, gas consumption, standoff distance, and scan speed provides a high-quality coating.

For thermal spraying, a torch is formed by applying an electrical potential between two electrodes, leading to ionization of an accelerated gas (a plasma). Torches of this type can readily reach temperatures of thousands of degrees Celsius, liquifying high melting point materials such as ceramics. Solid particles to be deposited are fed to the torch. The torch melts the solid particles of the desired material. The melted material is injected into the jet and then accelerated towards the component so that the molten or plasticized material coats the surface of the component body 204 and then is cooled, forming a solid, conformal coating. A carrier gas is pushed through an arc cavity and out through a nozzle. In the cavity, a cathode and anode comprise parts of the arc cavity and are maintained at a large direct current (DC) bias voltage, until the carrier gas begins to ionize, forming the plasma. Various types of thermal spraying include wire arc spraying, air plasma spraying, atmospheric plasma spraying (APS), suspension plasma spraying (SPS), low-pressure plasma spraying, high velocity oxy-fuel (HVOF), vacuum plasma spraying, and very low-pressure plasma spraying.

Alumina and yttria have a CTE of about 7. The CTE of aluminum is about 23. Metal oxyfluorides may have a CTE between about 7 and 30. So, an aluminum component body 204 with an anodized surface and an alumina coating over the anodized surface would have a resulting stress between the component body 204 and the alumina coating. The stresses would depend on the temperature at which the coating was deposited and the temperature at which various chamber processes are performed. Subjecting the component 200 to a wide variation of temperatures during wafer processing causes additional stresses.

In the prior art, an aluminum component body may have an alumina coating applied by APS. During the APS, alumina particles at a temperature higher than the melt temperature of alumina (greater than 2,600° C.) are deposited on a surface of the component body, causing the surface of the component body to be heated rapidly so that the alumina layer is deposited on a heated surface of the component body. For depositing other types of particles the particles are heated to a temperature above the precursor particle melt temperature. The component body is then quickly cooled. After being mounted in a plasma processing chamber and then used during wafer processing, the aluminum component body expands more than the metal oxide coating creating a tensile stress on the brittle alumina coating. The tensile stress creates channeling or tunneling cracks perpendicular to the interface between the aluminum component body and the alumina coating. The tunneling cracks may by themselves cause particles of the alumina coating to break away or spall from the component body. In other examples, the tunneling cracks along with additional stresses caused by deposition on the alumina may cause particles of the alumina coating to break away from the component body. The alumina coating particles are a source of contaminants. In addition, the breaking away of alumina particles may result in an unprotected surface of the aluminum component body. The unprotected aluminum component body could be eroded and the alumina coating may be undercut. These problems may be more pronounced during high temperature plasma processes.

This embodiment provides the ability to control the coating deposition temperature and time to control the CTE profile of the coating. The low temperature fluorination allows control of the temperature and time at which the fluorination is performed. A controlled low temperature fluorination allows for a controlled fluorination concentration gradient, providing a controlled stress gradient and controlled CTE along the z-axis. The controlled stress gradient and controlled CTE may be tuned to minimize local stresses, minimize particle generation, minimize delamination between different layers of material, and minimize cracking of the coating by providing a dispersed stress.

In various embodiments, the thickness of the fluorination of the yttria layer is dependent on the quality of the film. For a high density coating, fluorination extends to a depth from 100 nm to 5 μm. Aerosol deposition may be used to provide a high density coating that may be about 100 nm to 100 μm thick. A less dense and more porous layer may allow deeper fluorine diffusion. For example, a coating applied by APS may have a porosity of about 1% and a thickness in the range of 10 μm to 500 μm. The fluorination may be at least 10 μm to 500 μm deep. In some embodiments, the fluorination depth is equal to the thickness of the metal oxide coating, so that the fluorination reaches the surface of the component body. In various embodiments, the fluorination depth of the metal oxide layer is between 4 μm and 500 μm deep.

Various embodiments provide the low temperature fluorination at a temperature in the range of about 10° C. to 600° C. In other embodiments, the low temperature fluorination is performed at a temperature range of about 100° C. to 450° C. For components to be used in a plasma processing chamber at cryogenic temperatures, the low temperature fluorination may be provided at a temperature of less than 0° C. to provide reduced stresses during processing. However, the fluorination process temperatures below 0° C. may be too slow. If the fluorination is performed at a high temperature, for example at about 800° C., the resulting layer would be subject to a high stress. In addition, high temperature process may use a fluorocarbon gas. The use of fluorocarbon gas results in higher concentrations of carbon impurities in the resulting layer. The carbon impurities cause carbon contaminants during wafer processing. In various embodiments, the pressure provided during the low temperature fluorination may be between 0.1 bars (10 kPa) to 10 bars (100 kPa). The time period of the low temperature fluorination may be between 2 hours to 5 days depending upon the depth of fluorination desired, the temperature of the process, and the density of the layer to be fluorinated. Preferably, the low temperature fluorination is for a period of 3 hours to 2 days. In various embodiments, the fluorine containing gas is a gas containing a fluorine compound or fluorine compounds, where the fluorine compound has a partial pressure (or sum of partial pressures if more than one fluorine containing compound) in the range of 0.1-5 bar. In some embodiments, the fluorine containing gas may include hydrogen fluoride (HF) or fluorine radicals (e.g. plasma generated).

In another embodiment, a component body 204 of an yttria sintered material is provided (step 104). The component body 204 would be placed in a fluorination chamber. A low temperature fluorination process (step 108) provides a fluorine gas at a pressure of about 5 bars at a temperature of about 300° C. for about 24 hours. As a result, the surface of the component body 204 would have a high concentration of YF₃. The concentration of YF₃ decreases further away from the surface. In this example, most of the component body 204 would remain yttria. The resulting component may be used as a gas injector. The almost pure yttria component body 204 may have a CTE of about 7.2. The surface of YF₃ may have a CTE of between about 14 to 21. Along the depth extending from the surface of YF₃ the CTE diminishes from the CTE of YF₃ to the CTE of yttria. The transition of the CTE provides a low stress gradient along the thickness of the layer. A well tuned gradient results in a low stress gradient that is below any critical mechanical stress parameter of the layer that reduces or eliminates fracturing or cracking.

In another embodiment, the component body 204 is formed from sintered alumina. In this embodiment, the component body forms a dielectric inductive power window. An yttria layer is formed on a plasma facing surface of the dielectric window to provide a component with a metal oxide plasma facing surface (step 104). A low temperature fluorination process is used to fluorinate the yttria layer.

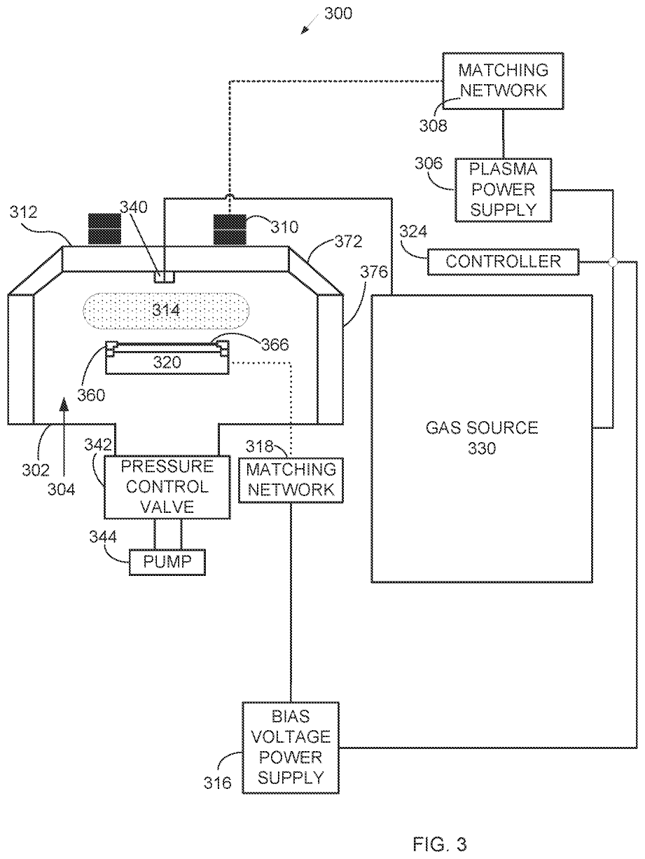

FIG. 3 schematically illustrates an example of a plasma processing chamber system 300 that may be used in an embodiment. The plasma processing chamber system 300 includes a plasma reactor 302 having a plasma processing confinement chamber 304 therein. A plasma power supply 306, tuned by a plasma matching network 308, supplies power to a transformer coupled plasma (TCP) coil 310 located near a dielectric inductive power window 312 to create a plasma 314 in the plasma processing confinement chamber 304 by providing an inductively coupled power. A pinnacle 372 extends from a chamber wall 376 of the plasma processing confinement chamber 304 to the dielectric inductive power window 312 forming a pinnacle ring. The pinnacle 372 is angled with respect to the chamber wall 376 and the dielectric inductive power window 312, such that the interior angle between the pinnacle 372 and the chamber wall 376 and the interior angle between the pinnacle 372 and the dielectric inductive power window 312 are each greater than 90° and less than 180°. The pinnacle 372 provides an angled ring near the top of the plasma processing confinement chamber 304, as shown. The TCP coil (upper power source) 310 may be configured to produce a uniform diffusion profile within the plasma processing confinement chamber 304. For example, the TCP coil 310 may be configured to generate a toroidal power distribution in the plasma 314. The dielectric inductive power window 312 is provided to separate the TCP coil 310 from the plasma processing confinement chamber 304 while allowing energy to pass from the TCP coil 310 to the plasma processing confinement chamber 304. A wafer bias voltage power supply 316 tuned by a bias matching network 318 provides power to an electrode 320 to set the bias voltage on the substrate 366. The electrode 320 is used as a substrate support to support the substrate 366. A controller 324 controls the plasma power supply 306 and the wafer bias voltage power supply 316.

The plasma power supply 306 and the wafer bias voltage power supply 316 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve desired process performance. For example, in one embodiment, the plasma power supply 306 may supply the power in a range of 50 to 5000 Watts, and the wafer bias voltage power supply 316 may supply a bias voltage of in a range of 20 to 2000 volts (V). In addition, the TCP coil 310 and/or the electrode 320 may be comprised of two or more sub-coils or sub-electrodes. The sub-coils or sub-electrodes may be powered by a single power supply or powered by multiple power supplies.

As shown in FIG. 3, the plasma processing chamber system 300 further includes a gas source/gas supply mechanism 330. The gas source 330 is in fluid connection with plasma processing confinement chamber 304 through a gas inlet, such as a gas injector 340. The gas injector 340 may be located in any advantageous location in the plasma processing confinement chamber 304 and may take any form for injecting gas. Preferably, however, the gas inlet may be configured to produce a “tunable” gas injection profile. The tunable gas injection profile allows independent adjustment of the respective flow of the gases to multiple zones in the plasma process confinement chamber 304. More preferably, the gas injector 340 is mounted to the dielectric inductive power window 312. The gas injector 340 may be mounted on, mounted in, or form part of the power window. The process gases and by-products are removed from the plasma process confinement chamber 304 via a pressure control valve 342 and a pump 344. The pressure control valve 342 and pump 344 also serve to maintain a particular pressure within the plasma processing confinement chamber 304. The pressure control valve 342 can maintain a pressure of less than 1 torr during processing. An edge ring 360 is placed around the substrate 366. The gas source/gas supply mechanism 330 is controlled by the controller 324. A Kiyo by Lam Research Corp. of Fremont, Calif., may be used to practice an embodiment.

In various embodiments, the component may be other parts of a plasma processing chamber, such as confinement rings, edge rings, the electrostatic chuck, ground rings, chamber liners such as the pinnacle, door liners, the dielectric inductive power window, or other components. Other components of other types of plasma processing chambers may be used. For example, plasma exclusion rings on a bevel etch chamber may be coated in an embodiment. In another example, the plasma processing chamber may be a dielectric processing chamber or conductor processing chamber. In some embodiments one or more, but not all surfaces are coated.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. A method for providing a component for using in a plasma processing chamber, wherein the component has a plasma facing surface, comprising:
providing a metal oxide layer on the plasma facing surface of the component; and
exposing the metal oxide layer to a gas containing at least one fluorine containing compound or fluorine containing compounds at a temperature of less than 600° C. for at least 2 hours at a partial pressure of the fluorine containing compound or a sum of partial pressures of the fluorine containing compounds of at least 0.1 bar.

2. The method, as recited in claim 1, wherein the providing the metal oxide layer, comprises forming a component body from metal oxide of the metal oxide layer, wherein the metal oxide layer is part of the component body.

3. The method as recited in claim 1, wherein the providing the metal oxide layer on the plasma facing surface of the component, comprises depositing the metal oxide layer on a component body.

4. The method, as recited in claim 3, wherein the depositing the metal oxide layer on the component body comprises depositing by at least one of thermal spraying and aerosol deposition.

5. The method, as recited in claim 3, wherein the metal oxide layer comprises yttria.

6. The method, as recited in claim 5, wherein the component body comprises at least one of an aluminum alloy and alumina.

7. The method as recited in claim 1, wherein the partial pressure or the sum of the partial pressures is in a range of 0.1 bar to 10 bar.

8. The method, as recited in claim 1, wherein the temperature is in a range of 10° C. to 450° C.

9. The method, as recited in claim 1, wherein the metal oxide layer comprises at least one of an oxide of a rare earth element and yttrium aluminum oxide.

10. The method, as recited in claim 1, wherein the component forms at least one of a liner, gas injector, edge ring, and dielectric inductive power window.

11. The method, as recited in claim 1, wherein the exposing the metal oxide layer to the gas is performed at a temperature less than 450° C.

12. The method, as recited in claim 1, wherein the fluorine containing compound or fluorine containing compounds comprise at least one of nitrogen trifluoride (NF₃), carbon tetrafluoride (CF₄), difluorine (F₂), methyl fluoride (CHₓF_{y}, where x and y are greater than or equal to one), sulfur hexafluoride (SF₆), and. chlorine trifluoride (ClF₃).

13. The method, as recited in claim 1, wherein the fluorine containing compound or fluorine containing compounds comprise difluorine (F₂).

14. A component for use in a plasma processing chamber, wherein the component has a component body with a plasma facing surface, wherein the plasma facing surface has a layer formed by a method as recited in claim 1.

15. A component for use in a plasma processing chamber, comprising:
a component body; and
a metal oxide containing layer forming a plasma facing surface of the component body, wherein metal oxide containing layer has an increasing fluoridation concentration closer to the plasma facing surface and wherein the metal oxide containing layer has less than 10 parts per million of carbon impurities by mass.

16. The component, as recited in claim 15, wherein the metal oxide containing layer comprises at least one of an oxide of a rare earth element and yttrium aluminum oxide.

17. The component, as recited in claim 15, wherein the metal oxide containing layer, comprises yttria.
